(19) United States
(12) Patent Application Publication
(10) Pub. No.: US 2016/0077914 A1
(43) Pub. Date: Mar. 17, 2016

(54) SOLID STATE STORAGE DEVICE AND ERROR CORRECTION METHOD THEREOF

(71) Applicant: LITE-ON TECHNOLOGY CORPORATION, Taipei (TW)

(72) Inventors: Shih-Jia Zeng, Taipei (TW); Sheng-Han Wu, Taipei (TW); Jen-Chien Fu, Taipei (TW); Yu-Shan Wu, Taipei (TW)

(21) Appl. No.: 14/644,656

(22) Filed: Mar. 11, 2015

(30) Foreign Application Priority Data
Sep. 12, 2014 (CN) 201410465339.9

(51) Int. Cl. G06F 11/10; H03M 13/11; H03M 13/45; G11C 29/52

(52) U.S. Cl. CPC G06F 11/1068; G06F 11/1072; G11C 29/52; H03M 13/1148; H03M 13/45

(57) ABSTRACT

An error correction method for a solid state storage device is provided. A controller of the solid state storage device issues plural slicing voltages to a flash memory. The flash memory issues a soft data to a soft decoder of the controller according to the plural slicing voltages. Firstly, the soft decoder receives the soft data, and performs an error correction process of the soft data according to a predetermined log-likelihood ratio (LLR) parameter set. If the error correction process of the soft data is not successfully completed according to the predetermined LLR parameter set, one LLR parameter set is selected from plural parameter sets of a LLR table and the error correction process of the soft data is performed according to the selected LLR parameter set.

This application claims the benefit of People's Republic of China Patent Application No. 201410465339.9, filed Sep. 12, 2014, the subject matter of which is incorporated herein by reference.

### FIELD OF THE INVENTION

The present invention relates to a solid state storage device and an error correction method, and more particularly to a solid state storage device with a soft decoder and an error correction method thereof.

### BACKGROUND OF THE INVENTION

As is well known, the solid state storage devices using NAND-based flash memories are widely used in a variety of electronic devices. For example, a SD card or a solid state drive (SSD) is a solid state storage device that uses a NAND-based flash memory to store data.

FIG. 1 is a schematic functional block diagram illustrating a conventional solid state storage device. As shown in FIG. 1, the solid state storage device 100 comprises a controller 150, a buffer 170 and a flash memory 160. The controller 150 is connected with the buffer 170 and the flash memory 160. In addition, the solid state storage device 100 is in communication with a host 120 through an external bus 110.

For example, when the host 120 issues a write command and a write address to the controller 150, a write data is transmitted from the host 120 to the controller 150. In addition, an error correction code (ECC code) is correspondingly generated by a hard codec 155 of the controller 150. The write data and the ECC code are written into the flash memory 160 together. On the other hand, when the host 120 issues a read command and a read address to the controller 150, the corresponding read data and the ECC code are read out from the flash memory 160 by the controller 150. After an error correction process is successfully completed by the hard codec 155, the accurate read data can be transmitted from the controller 150 to the host 120. Moreover, the buffer 170 is used for temporarily storing the read data and the write data.

Generally, each memory cell of the flash memory 160 comprises a floating gate transistor. The floating gate transistor has a floating gate to store hot carriers. According to the amount of the stored hot carriers, a threshold voltage (V_{TH}) of the floating gate transistor and a storing state of the memory cell can be determined.

Depending on the stored data amount per memory cell, the NAND-based flash memories may be classified into three types, i.e. a single-level cell (SLC) flash memory, a multi-level cell (MLC) flash memory and a triple-level cell (TLC) flash memory. The SLC flash memory can store only one bit of data per cell. The MLC flash memory can store two bits of data per cell. The TLC flash memory can store three bits of data per cell. Hereinafter, the characteristics of the NAND-based flash memory will be described by referring to the SLC flash memory.

FIG. 2 schematically illustrates the threshold voltage distribution curves of the SLC flash memory in different storing states. Generally, each memory cell of the SLC flash memory has two storing states A and B. Before the hot carriers are injected into the memory cell, the memory cell has the storing state A (e.g. the logic state “1”). After the hot carriers are injected into the memory cell, the memory cell has the storing state B (e.g. the logic state “0”).

Due to the characteristics of the memory cells, the memory cells in the same storing state (e.g. the storing state B) may have different threshold voltages. Generally, the threshold voltages of these memory cells are distributed in a specified distribution curve with a median threshold voltage. Similarly, the threshold voltages of the memory cells in the storing state A are distributed in a specified distribution curve with a median threshold voltage.

As shown in FIG. 2, the memory cells in the storing state A have a median threshold voltage V_{THA} (e.g. 5V), and the memory cells in the storing state B have a median threshold voltage V_{THB} (e.g. 20V). That is, according to statistics, a greater number of the memory cells in the storing state A have the median threshold voltage V_{THA}, and a greater number of the memory cells in the storing state B has the median threshold voltage V_{THB}.

Moreover, during a read cycle, a slicing voltage Vs1 is applied to the floating gate transistor of the memory cell. According to the slicing voltage Vs1, the controller 150 may realize the storing state of each memory cell by determining whether the memory cell is turned on. After the slicing voltage Vs1 is applied to the floating gate transistor of the memory cell, if the memory cell is turned on, the storing state of the memory cell is the storing state A. Whereas, if the memory cell cannot be turned on, the storing state of the memory cell is the storing state B.

Please refer to FIG. 2 again. In the threshold voltage distribution curve of the storing state A, the threshold voltages of the memory cells corresponding to the region “a” are higher than the slicing voltage Vs1. Similarly, in the threshold voltage distribution curve of the storing state B, the threshold voltages of the memory cells corresponding to the region “b” are lower than the slicing voltage Vs1. Consequently, during the read cycle, the storing state A of the memory cells corresponding to the region “a” is erroneously judged as the storing state B, and the storing state B of the memory cells corresponding to the region “b” is erroneously judged as the storing state A. Under this circumstance, it is necessary to correct the erroneously-judged memory cells by using the hard codec 155 of the controller 155.

In the solid state storage device 100, the hard codec 155 of the controller 155 is for example a BCH codec. The controller 150 may provide the slicing voltage Vs1 to discriminate the two storing states of the memory cells. Moreover, the hard codec 155 of the controller 150 may correct the erroneously-judged memory cells.

However, after the memory cells of the flash memory 160 have been programmed and erased many times, the characteristics of the memory cells are gradually suffered from degradation. Consequently, the use life of the flash memory 160 is shortened. Moreover, since the number of the erroneously-judged memory cells of the flash memory 160 increases, the data error rate also increases. Under this circumstance, the hard codec 155 is unable to successfully correct the erroneous memory cells.

For solving the above drawbacks, the controller 150 has to perform a calibration process to update the slicing voltage Vs1. Then, a read retry operation is performed on the flash memory 160 according to the updated slicing voltage Vs1. Then, the hard codec 155 is employed to correct the erroneously-judged memory cells. We can call above process as “Vs1 update iteration”. According to the past experience, it is not easy to correct all the errors within three Vs1 update iterations. For successfully decoding the data, it is necessary to increase the number of times of updating the slicing voltage Vs1 and then read the flash memory and decode the data. As known, it is time-consuming to frequently update the slicing voltage Vs1.

### SUMMARY OF THE INVENTION

An embodiment of the present invention provides a solid state storage device. The solid state storage device is in communication with a host. The solid state storage device has a controller, a flash memory and a buffer. The controller is in communication with the host. The controller includes a soft decoder. The flash memory is connected to the controller and receives plural slicing voltages from the controller. The flash memory issues a soft data according to the plural slicing voltages. The buffer is connected to the controller. The soft decoder performs an error correction process of the soft data according to a predetermined log-likelihood ratio (LLR) parameter set. If the error correction process of the soft data is not successfully completed according to the predetermined LLR parameter set, the controller selects another LLR parameter set from a LLR table, which contains plurality of parameter sets, and the soft decoder performs the error correction process of the soft data according to the selected LLR parameter set.

Another embodiment of the present invention provides an error correction method for a solid state storage device. A controller of the solid state storage device issues plural slicing voltages to a flash memory. The flash memory issues a soft data to a soft decoder of the controller according to the plural slicing voltages. Firstly, the soft decoder receives the soft data, and performs an error correction process of the soft data according to a predetermined log-likelihood ratio (LLR) parameter set. If the error correction process of the soft data is not successfully completed according to the predetermined LLR parameter set, another LLR parameter set is selected from plural parameter sets of a LLR table and the error correction process of the soft data is performed according to the selected LLR parameter set.

That is, if the error correction process of the soft data is not successfully completed according to the predetermined LLR parameter set, the controller only needs to replace the predetermined LLR parameter set by a newly selected LLR parameter set, which is selected from the LLR table, without need of performing the read retry operation on the flash memory. Consequently, the error correction method of the present invention is time-saving. Since the LLR table contains plural LLR parameter sets, if the data cannot be successfully decoded, the error correction process of the soft data can be performed according to these LLR parameter sets. Moreover, if the data cannot be successfully decoded according to all of these LLR parameter sets in the LLR table, it means that the original slicing voltages are possibly too large or too small. Meanwhile, the controller may perform the slicing voltage calibration process to update the plural slicing voltages, that is what we mentioned the “Vs1 update iteration”.

Numerous objects, features and advantages of the present invention will be readily apparent upon a reading of the following detailed description of embodiments of the present invention when taken in conjunction with the accompanying drawings. However, the drawings employed herein are for the purpose of descriptions and should not be regarded as limiting.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1 (prior art) is a schematic functional block diagram illustrating a conventional solid state storage device;

FIG. 2 (prior art) schematically illustrates the threshold voltage distribution curves of the SLC flash memory in different storing states;

FIG. 3 is a schematic functional block diagram illustrating a solid state storage device according to an embodiment of the present invention;

FIG. 4 schematically illustrates the threshold voltage distribution curves of the SLC flash memory in different storing states and the relationship between a hard slicing voltage, a first soft slicing voltage and a second soft slicing voltage; and

FIG. 5 is a flowchart illustrating an error correction method for a solid state storage device according to an embodiment of the present invention.

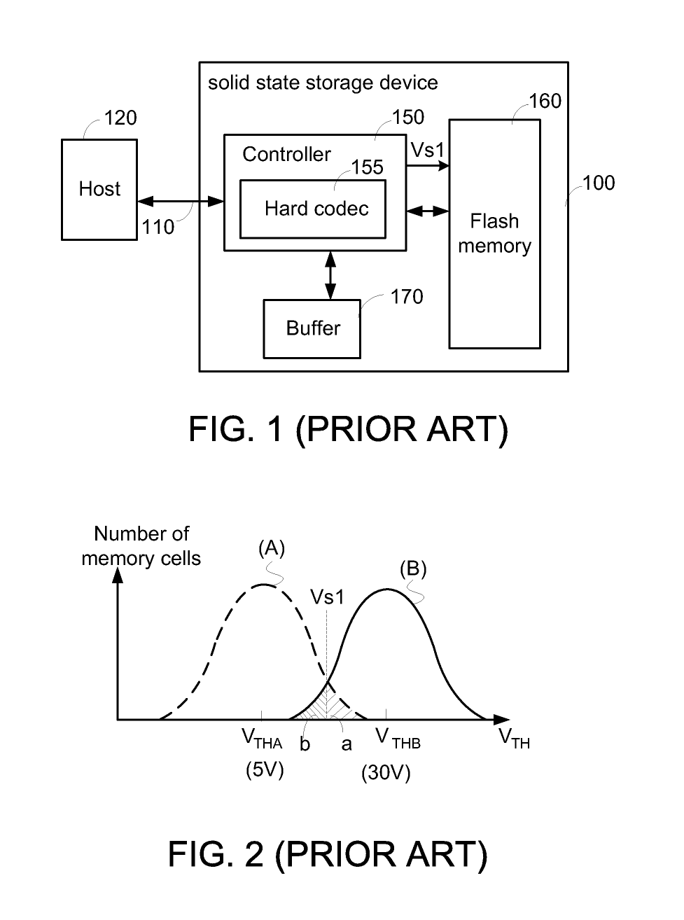

### DETAILED DESCRIPTION OF PREFERRED EMBODIMENTS

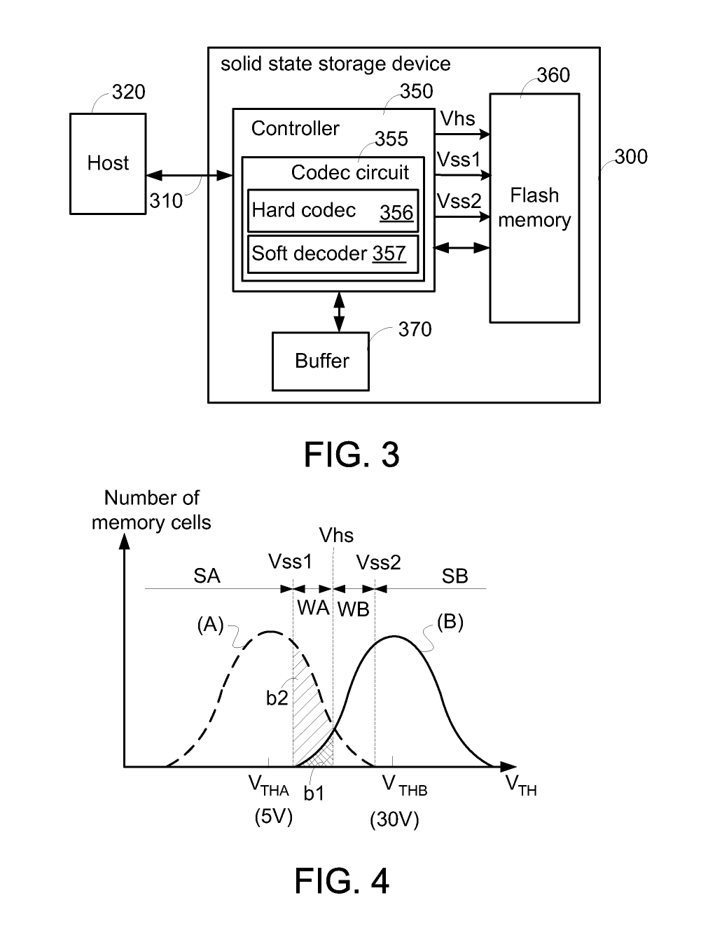

FIG. 3 is a schematic functional block diagram illustrating a solid state storage device according to an embodiment of the present invention. As shown in FIG. 3, the solid state storage device 300 comprises a controller 350, a buffer 370 and a flash memory 360. The controller 350 is connected with the buffer 370 and the flash memory 360. In addition, the solid state storage device 300 is in communication with a host 320 through an external bus 310.

The controller 350 comprises a codec circuit 355. The codec circuit 355 comprises a hard codec 356 and a soft decoder 357. For example, the codec circuit 355 is a low-density parity check codec (also referred as a LDPC codec).

When the host 320 issues a write command and a write address to the controller 350, a write data is transmitted from the host 320 to the controller 350. In addition, an error correction code (ECC code) is correspondingly generated by the codec circuit 355 of the controller 350. The write data and the ECC code are written into the flash memory 360 together. On the other hand, when the host 320 issues a read command and a read address to the controller 350, the corresponding read data and the ECC code are read out from the flash memory 360 by the controller 350. After the error is corrected by the codec circuit 355, the accurate read data can be transmitted from the controller 350 to the host 320.

Since the codec circuit 355 of the controller 350 comprises the hard codec 356 and the soft decoder 357, the controller 350 can selectively utilize the hard codec 356 or the soft decoder 357 to perform an error correction process according to the condition of the read data.

Generally, the soft decoder 357 has better error correction capability. Consequently, if the error correction process cannot be completed by the hard codec 356 or the data error rate is too high, the controller 350 may utilize the soft decoder 357 to verify the errors of the read data.

In case that the hard codec 356 is used to correct and/or verify the data of the memory cells, the controller 350 provides a hard slicing voltage Vhs to the flash memory 360 in order to discriminate the storing states of the memory cells. The read data obtained according to the hard slicing voltage Vhs are also referred as hard data.

FIG. 4 schematically illustrates the threshold voltage distribution curves of the SLC flash memory in different storing states and the relationship between a hard slicing voltage, a first soft slicing voltage and a second soft slicing voltage. Please refer to FIG. 4. After a hard slicing voltage Vhs is applied to the memory cell, if the memory cell is turned on, the storing state of the memory cell is the storing state A. Whereas, if the memory cell cannot be turned on, the storing state of the memory cell is the storing state B. Consequently, the storing state B of the memory cells corresponding to the left-side region of the hard slicing voltage Vhs is erroneously judged as the storing state A, and the storing state A of the memory cells corresponding to the right-side region of the hard slicing voltage Vhs is erroneously judged as the storing state B. The hard codec 356 is used for correcting the erroneously-judged memory cells of hard data.

While the soft decoder 357 is utilized to correct and/or verify the data of the memory cell, the controller 350 provides the hard slicing voltage Vhs, a first soft slicing voltage Vss1 and a second soft slicing voltage Vss2 to the flash memory 360 in order to discriminate the storing states of the memory cells. The read data obtained according to the plural slicing voltages are also referred as soft data.

As shown in FIG. 4, the first soft slicing voltage Vss1 is smaller than the hard slicing voltage Vhs, and the hard slicing voltage Vhs is smaller than the second soft slicing voltage Vss2. After the controller 350 sequentially provides the three slicing voltages to the flash memory 360 to discriminate the storing states of the memory cells, the following four possible results may be generated.

If the threshold voltage of the memory cell lies in a SA zone at the left side of the first soft slicing voltage Vss1, the memory cell is determined to have a strong storing state A. If the threshold voltage of the memory cell lies in a WA zone between the first soft slicing voltage Vss1 and the hard slicing voltage Vhs, the memory cell is determined to have a weak storing state A. If the threshold voltage of the memory cell lies in a WB zone between the hard slicing voltage Vhs and the second soft slicing voltage Vss2, the memory cell is determined to have a weak storing state B. If the threshold voltage of the memory cell lies in a SB zone at the right side of the second soft slicing voltage Vss2, the memory cell is determined to have a strong storing state B. Consequently, the soft decoder 357 may correct the erroneously-judged memory cells according to the above criteria.

Moreover, the soft decoder 357 performs the error correction process of the soft data according to a log-likelihood ratio (LLR) parameter set. Generally, the LLR parameter set may be obtained according to the relationship between the distribution curves of the storing states A and B.

The LLR value of each zone is defined according to the following logarithm function: LRR=log₂[P(x=B)/P(x=A)]. The base of the logarithm function is 2. It is noted that any other logarithm function with a different base is also feasible. Alternatively, the LLR value may be defined according to the natural logarithm function. In the above formula, P(x=B) denotes the probability of the storing state B for the x-th bit, and P(x=A) denotes the probability of the storing state A for the x-th bit.

For example, the area of the distribution curve of the storing state B in the WA zone is b1, and the area of the distribution curve of the storing state A in the WA zone is b2. Consequently, the LLR value corresponding to the WA zone is equal to log₂[b1/b2].

If the probability of the storing state A and the probability of the storing state B in the SA zone are 0.9 and 0.1, respectively, the LLR value corresponding to the SA zone is equal to log₂[0.1/0.9]=−3.17. If the probability of the storing state A and the probability of the storing state B in the WA zone are 0.7 and 0.3, respectively, the LLR value corresponding to the WA zone is equal to log₂[0.3/0.7]=−1.22. If the probability of the storing state A and the probability of the storing state B in the WB zone are 0.3 and 0.7, respectively, the LLR value corresponding to the WB zone is equal to log₂[0.7/0.3]=+1.22. If the probability of the storing state A and the probability of the storing state B in the SB zone are 0.1 and 0.9, respectively, the LLR value corresponding to the WB zone is equal to log₂[0.9/0.1]=+3.17.

Obviously, the negative LLR value denotes the higher probability of the storing state A for the memory cell, and the positive LLR value denotes the higher probability of the storing state B for the memory cell. Moreover, the LLR value smaller than −3.17 indicates that the probability of the storing state A for the memory cell is higher than 90%, and the LLR value larger than +3.17 indicates that the probability of the storing state B for the memory cell is higher than 90%.

In other words, the soft decoder 357 may perform the error correction process of the soft data according to the LLR parameter set containing the LLR values −3.17, −1.22, +1.22 and +3.17. The SA zone (i.e. the strong storing state A) corresponds to the LLR value of −3.17. The WA zone (i.e. the weak storing state A) corresponds to the LLR value of −1.22. The WB zone (i.e. the weak storing state B) corresponds to the LLR value of +1.22. The SB zone (i.e. the strong storing state B) corresponds to the LLR value of +3.17. The soft decoder 357 may perform the error correction process of the soft data according to the LLR parameter set.

Similarly, after the memory cells of the flash memory 360 have been programmed and erased many times, the characteristics of the memory cells are gradually suffered from degradation. Consequently, the use life of the flash memory 360 is shortened. Moreover, since the number of the erroneously-judged memory cells of the flash memory 360 increases, the data error rate also increases. Under this circumstance, the soft decoder 357 is unable to successfully correct the erroneous memory cells.

For solving the above drawbacks, the controller 350 may perform a calibration process to update the hard slicing voltage Vhs, the first soft slicing voltage Vss1 and the second soft slicing voltage Vss2. Then, a read retry operation is performed on the flash memory 360 according to the updated slicing voltages Vhs, Vss1 and Vss2. Then, the soft decoder 357 is employed to correct the erroneously-judged memory cells.

However, the time period for performing the slicing voltage calibration process is relatively long (e.g. about 50˜100 μs). It is time-consuming to perform the slicing voltage calibration process frequently. The present invention provides an error correction method for a solid state storage device. In this error correction method, the soft decoder 357 performs the error correction process of the soft data with different LLR parameter set if necessary.

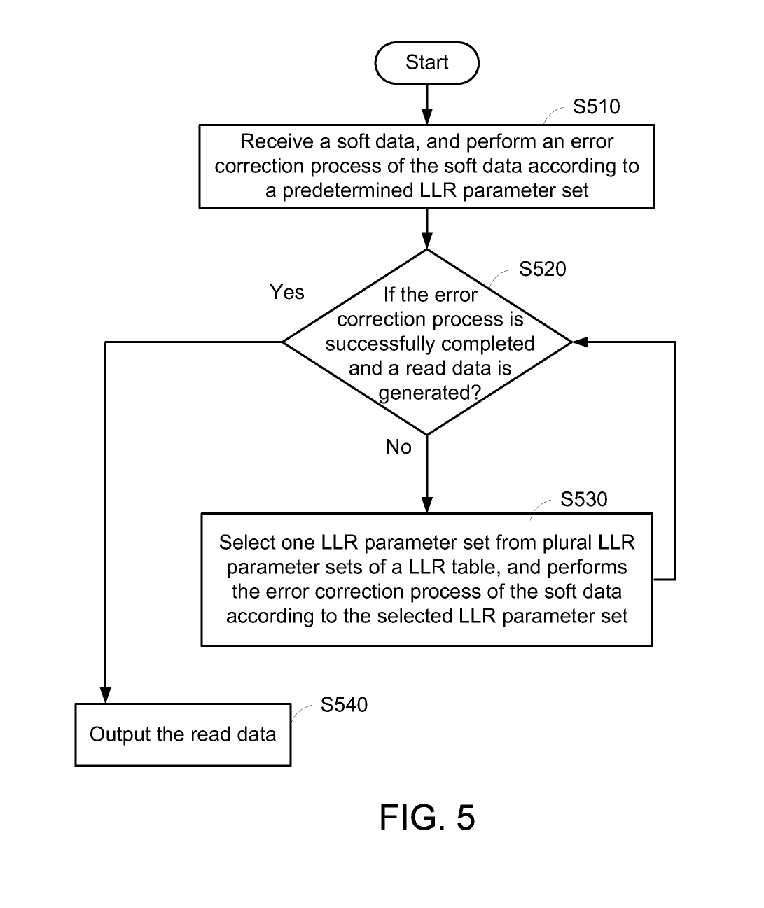

FIG. 5 is a flowchart illustrating an error correction method for a solid state storage device according to an embodiment of the present invention. In this error correction method, the soft decoder 357 of the controller 350 is utilized to perform the error correction process.

Firstly, plural slicing voltages including a hard slicing voltage and at least two soft slicing voltages are provided to the flash memory 360. Consequently, a soft data is transmitted from the flash memory 360 to the controller 350. After the soft data is received by the soft decoder 357, the soft decoder 357 performs an error correction process of the soft data according to a predetermined LLR parameter set (Step S510).

If the error correction process is successfully completed and a read data is generated (Step S520), the read data is generated and transmitted from the soft decoder 357 to the host 320 (Step S540).

Whereas, if the judging condition of the step S520 is not satisfied, another LLR parameter set is selected from plural LLR parameter sets of a LLR table, and the soft decoder 357 performs the error correction process of the soft data according to the selected LLR parameter set (Step S530). Then, the judging procedure of the step S520 is repeatedly performed.

In other words, the LLR table containing plural LLR parameter sets is previously stored in the program where the controller 150 is executing. When the soft decoder 357 fails to successfully complete the error correction process of the soft data and generate the read data, the controller 350 may select one of the plural LLR parameter set from the LLR table in replacing of the predetermined LLR parameter set and the soft decoder 357 may perform the error correction process of the soft data again.

Since the time period of updating the LLR parameter set of the soft decoder 357 is relatively short, it takes about 1000 ns to perform another error correction process on soft data with updated LLR parameter set. In comparison with the slicing voltage calibration process (e.g. 50˜100 μs), the error correction method of the present invention is time-saving.

Moreover, if the soft decoder 357 still fails to successfully generate the read data after at least one of the LLR parameter set in the LLR table are used, the controller 350 may perform the slicing voltage calibration process again to update the hard slicing voltage Vhs, the first soft slicing voltage Vss1 and the second soft slicing voltage Vss2. Then, a read retry operation is performed on the flash memory 360 according to the updated slicing voltages Vhs, Vss1 and Vss2, so that another soft data is obtained. Then, the soft decoder 357 is employed to correct the erroneously-judged memory cells.

From the above descriptions, the present invention provides an error correction method for a solid state storage device. Consequently, the error correction process of the soft data can be quickly implemented by the soft decoder 357.

In the above embodiment, the controller 350 comprises both the hard codec 356 and the soft decoder 357. However, even if the controller only includes the soft decoder, the controller can still implement the error correction method of the present invention.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A solid state storage device in communication with a host, the solid state storage device comprising:
a controller in communication with the host, wherein the controller comprises a soft decoder;
a flash memory connected to the controller and receiving plural slicing voltages from the controller, wherein the flash memory issues a soft data according to the plural slicing voltages; and
a buffer connected to the controller,
wherein the soft decoder performs an error correction process of the soft data according to a predetermined log-likelihood ratio (LLR) parameter set, wherein if the error correction process of the soft data is not successfully completed according to the predetermined LLR parameter set, the controller selects another LLR parameter set from a LLR table and the soft decoder performs the error correction process of the soft data according to the selected LLR parameter set.

2. The solid state storage device as claimed in claim 1, wherein the soft decoder is a low-density parity check (LDPC) decoder.

3. The solid state storage device as claimed in claim 1, wherein if the error correction process of the soft data is not successfully completed according to at least one of the selected LLR parameter set of the LLR table, a slicing voltage calibration process is performed to update the plural slicing voltages.

4. The solid state storage device as claimed in claim 1, wherein the plural slicing voltages includes a hard slicing voltage, a first soft slicing voltage and a second soft slicing voltage, wherein the hard slicing voltage is larger than the first soft slicing voltage, and the hard slicing voltage is smaller than the second soft slicing voltage.

5. The solid state storage device as claimed in claim 1, wherein if the error correction process of the soft data is successfully completed according to the predetermined LLR parameter set, the soft decoder generates a read data to the host.

6. An error correction method for a solid state storage device, a controller of the solid state storage device issuing plural slicing voltages to a flash memory, the flash memory issuing a soft data to a soft decoder of the controller according to the plural slicing voltages, the error correction method comprising steps of:
the soft decoder receiving the soft data, and performing an error correction process of the soft data according to a predetermined log-likelihood ratio (LLR) parameter set; and
if the error correction process of the soft data is not successfully completed according to the predetermined LLR parameter set, selecting one LLR parameter set from plural parameter sets of a LLR table and performing the error correction process of the soft data according to the selected LLR parameter set.

7. The error correction method as claimed in claim 6, wherein the soft decoder is a low-density parity check (LDPC) decoder.

8. The error correction method as claimed in claim 6, wherein if the error correction process of the soft data is not successfully completed according to at least one of the LLR parameter set of the LLR table, performing a slicing voltage calibration process to update the plural slicing voltages.

9. The error correction method as claimed in claim 6, wherein the plural slicing voltages includes a hard slicing voltage, a first soft slicing voltage and a second soft slicing voltage, wherein the hard slicing voltage is larger than the first soft slicing voltage, and the hard slicing voltage is smaller than the second soft slicing voltage.

10. The error correction method as claimed in claim 6, wherein if the error correction process of the soft data is successfully completed according to the predetermined LLR parameter set, generating a read data.
